(19) United States
(12) Patent Application Publication
(10) Pub. No.: US 2003/0020122 A1
(43) Pub. Date: Jan. 30, 2003

(54) Methods of forming integrated circuit electrodes and capacitors by wrinkling a layer that includes a noble metal oxide, and integrated circuit electrodes and capacitors fabricated thereby

(76) Inventors: Jae Hyun Joo, Seoul (KR); Wandon Kim, Kyunggi-do (KR); Soonyeon Park, Taegu-City (KR); Seokjun Won, Seoul (KR)

Correspondence Address: MYERS BIGEL SIBLEY & SAJOVEC, PO BOX 37428, RALEIGH, NC, 27627, US

(21) Appl. No.: 10/201,070

(22) Filed: Jul. 23, 2002

Related U.S. Application Data
(60) Provisional application No. 60/307,454, filed on Jul. 24, 2001.

(51) Int. Cl. H01L 29/76; H01L 29/94; H01L 31/062; H01L 31/113; H01L 31/119

(52) U.S. Cl. 257/381

(57) ABSTRACT

An integrated circuit electrode is fabricated by forming a layer of noble metal oxide, such as ruthenium oxide, on an integrated circuit substrate, and wrinkling the layer of noble metal oxide by removing at least some oxygen from the layer of noble metal oxide, to thereby produce a wrinkled layer. Wrinkling may be performed by exposing the layer of noble metal oxide to a reducing ambient, and/or by deoxidizing the layer of noble metal oxide. A dielectric layer and a second electrode may be added to form a capacitor. These integrated circuit electrodes and capacitors can include a wrinkled layer having subhemispherical protrusions of noble metal, and that do not include superhemispherical protrusions of noble metal.

### CROSS-REFERENCE TO RELATED APPLICATIONS

This application claims the benefit of provisional Application Serial No. 60/307,454, filed Jul. 24, 2001, the disclosure of which is hereby incorporated herein by reference in its entirety as if set forth fully herein.

### FIELD OF THE INVENTION

This invention relates to integrated circuit devices and fabrication methods, and more particularly to integrated circuit electrodes and capacitors and fabrication methods therefor.

### BACKGROUND OF THE INVENTION

Integrated circuit devices are widely used in consumer and commercial applications. Many integrated circuit devices include integrated circuit capacitors therein. For example, many memory devices, such as Dynamic Random Access Memory (DRAM) devices, include integrated circuit capacitors. As is well known to those having skill in the art, an integrated circuit capacitor generally includes a first (lower) electrode, a second (upper) electrode and a dielectric therebetween.

As the integration density of integrated circuit devices continues to increase, it may become desirable to increase the capacitance per unit area of an integrated circuit capacitor. As is well known, the capacitance per unit area may be increased by increasing the effective area of the capacitor, by decreasing the thickness of the dielectric, and/or by increasing the dielectric constant of the dielectric material.

Three-dimensional electrode structures, such as cylindrical, finned and/or trench electrode structures have been developed, to thereby increase the effective area of the capacitor per unit area in the integrated circuit substrate. It is also known to form hemispherical grain silicon electrodes, to increase the surface area of an integrated circuit electrode per unit area of the integrated circuit substrate. See, for example, U.S. Pat. Nos. 6,333,227; 6,245,632; 6,238,973; 6,117,692; 6,087,226; 6,077,573; 6,004,858; 5,960,281; 5,885,867 and 5,821,152, all of which are assigned to the assignee of the present invention, the disclosures of all of which are hereby incorporated herein by reference in their entirety as if set forth fully herein.

It may be desirable to use metal as an integrated circuit electrode, such as a lower electrode of an integrated circuit capacitor, rather than silicon or polysilicon. For example, noble metals, such as platinum (Pt), ruthenium (Ru) and/or iridium (Ir) and/or their oxides may be used as an integrated circuit electrode, such as a lower electrode. In particular, ruthenium-based electrodes, including ruthenium oxide-based electrodes, may be etched by oxygen-containing plasma to form a conductive metal oxide layer. Thus, ruthenium-based electrodes may be particularly desirable.

It is known to increase the surface area of noble metal-containing electrodes using high temperature agglomeration, sputtering and/or oxygen plasma treatments. See, for example, Japanese Publication No. 10-270662, published Oct. 9, 1998 to Takeharu entitled Semiconductor Storage Device Having Capacitor and Its Manufacture; Japanese Publication No. 11-121711, published Apr. 30, 1999 to Teruo et al. entitled Manufacture of Capacitor, Manufacture of Semiconductor Device Capacitor and Semiconductor Device Capacitor; and published PCT Publication No. WO 00/13216, published Mar. 9, 2000 to Marsh et al. entitled Capacitors Comprising Roughened Platinum Layers, Methods of Forming Roughened Layers of Platinum and Methods of Forming Capacitors.

### SUMMARY OF THE INVENTION

Some embodiments of the present invention fabricate an integrated circuit electrode by forming a layer comprising noble metal oxide, such as ruthenium oxide, on an integrated circuit substrate, and wrinkling the layer comprising noble metal oxide by removing at least some oxygen from the layer comprising noble metal oxide, to thereby produce a wrinkled layer. Other embodiments of the present invention fabricate an integrated circuit electrode by forming a layer comprising noble metal oxide on an integrated circuit substrate and wrinkling the layer comprising noble metal oxide, by exposing the layer comprising noble metal oxide to a reducing ambient, to thereby produce a wrinkled layer.

Still other embodiments of the present invention fabricate an integrated circuit electrode by forming a layer comprising noble metal oxide on an integrated circuit substrate and wrinkling the layer comprising noble metal oxide by deoxidizing the layer comprising noble metal oxide, to thereby produce a wrinkled layer. Yet other embodiments of the present invention fabricate an integrated circuit electrode by forming a layer comprising metal and another constituent on an integrated circuit substrate and wrinkling the layer comprising metal and another constituent by removing at least some of the other constituent from the layer comprising metal and another constituent, to thereby produce a wrinkled layer.

Other embodiments of the present invention fabricate an integrated circuit electrode by forming a layer comprising metal and another constituent on an integrated circuit substrate, and wrinkling the layer comprising metal and another constituent by reacting at least some of the metal with at least some of the other constituent, to form a compound of the metal and the other constituent, and thereby produce a wrinkled layer. Yet other embodiments of the present invention fabricate an integrated circuit electrode by forming a layer comprising noble metal having a volume on an integrated circuit substrate and wrinkling the layer comprising noble metal by decreasing the volume of the layer comprising noble metal on the integrated circuit substrate.

Still other embodiments of the invention fabricate an integrated circuit capacitor by forming a first layer comprising ruthenium on an integrated circuit substrate and forming a second layer comprising ruthenium oxide on the first layer opposite the integrated circuit substrate. The second layer is exposed to a reducing ambient to produce a wrinkled second layer. A third layer comprising tantalum oxide is formed on the wrinkled second layer opposite the first layer. A fourth layer comprising ruthenium is formed on the third layer opposite the second layer.

Integrated circuit electrodes according to some embodiments of the present invention include an integrated circuit substrate and a wrinkled layer comprising a plurality of subhemispherical protrusions that comprise noble metal, on the integrated circuit substrate. In other embodiments the wrinkled layer consists essentially of a plurality of subhemispherical protrusions and in still other embodiments the wrinkled layer is free of superhemispherical protrusions that comprise noble metal on the integrated circuit substrate. In yet other embodiments, integrated circuit capacitors can also include a dielectric layer on the wrinkled layer opposite the substrate and a conductive layer on the dielectric layer opposite the wrinkled layer.

Integrated circuit electrodes according to other embodiments of the present invention include a first layer comprising ruthenium on an integrated circuit substrate. A second wrinkled layer comprising a plurality of subhemispherical ruthenium protrusions is provided on the first layer opposite the integrated circuit substrate. Integrated circuit capacitors according to some embodiments of the invention also include a third layer comprising tantalum oxide on the second layer opposite the first layer, and a fourth layer comprising ruthenium on the third layer opposite the second layer.

In some embodiments, the layer comprising noble metal oxide can be formed by sputtering. In other embodiments, the layer comprising noble metal oxide can be formed by depositing the noble metal on the integrated circuit substrate in an oxygen-containing ambient. In still other embodiments, the layer comprising noble metal oxide may be fabricated by depositing the noble metal on the integrated circuit substrate and oxidizing at least some of the noble metal.

In other embodiments, prior to forming a layer comprising noble metal oxide, a barrier layer is formed on the integrated circuit substrate. In some embodiments, the barrier layer comprises a noble metal. In other embodiments, the barrier layer comprises titanium nitride and/or other conventional materials.

In some embodiments, wrinkling is performed by wrinkling the layer comprising noble metal oxide without uncovering an underlying region of the integrated circuit substrate directly beneath the wrinkled layer. In other embodiments, the underlying region may be partially uncovered.

In some embodiments, wrinkling is performed by exposing the layer comprising noble metal oxide to a reducing ambient, to remove at least some oxygen from the layer comprising noble metal oxide. In other embodiments, wrinkling is performed by removing all the oxygen from the layer comprising noble metal oxide, to produce a wrinkled layer consisting essentially of noble metal. In some embodiments, the reducing ambient comprises a hydrogen-containing ambient. In other embodiments, the hydrogen-containing ambient consists of hydrogen. In still other embodiments, the hydrogen-containing ambient consists of between about 1% and about 100% hydrogen, and between about 0% and about 99% inert gas.

In some embodiments, the wrinkled layer is of smaller volume than the layer comprising noble metal oxide. In other embodiments, the wrinkled layer is thinner than the layer comprising noble metal oxide.

In other embodiments, the other constituent comprises carbon and wrinkling is performed by heating the layer comprising noble metal and carbon, to remove at least some of the carbon and wrinkle the layer comprising noble metal and carbon. In yet other embodiments, the metal comprises a noble metal and the other constituent comprises oxygen, and the wrinkling comprises exposing the layer comprising noble metal and oxygen to a reducing ambient, to remove at least some of the oxygen and wrinkle the layer comprising noble metal and oxygen.

In still other embodiments, the metal comprises a noble metal and the other constituent comprises silicon, and wrinkling is performed by heating the layer comprising noble metal and silicon, to react at least some of the noble metal with at least some of the silicon, to form a noble metal silicide, and thereby wrinkle the layer comprising noble metal and silicon.

### BRIEF DESCRIPTION OF THE DRAWINGS

FIGS. 1A and 1B are cross-sectional views of integrated circuit electrodes according to some embodiments of the present invention during intermediate fabrication steps according to some embodiments of the present invention.

FIG. 1C is a cross-sectional view of integrated circuit capacitors according to some embodiments of the present invention.

FIGS. 2A-2D are cross-sectional views of integrated circuit electrodes according to other embodiments of the invention during intermediate fabrication steps according to other embodiments of the invention.

FIGS. 3A, 4A, 5A and 6A are cross-sectional images of ruthenium oxide layers that were annealed in various ambient atmospheres according to some embodiments of the present invention.

FIGS. 3B, 4B, 5B and 6B are top perspective images of ruthenium oxide layers that were annealed in various ambient atmospheres according to some embodiments of the present invention.

FIGS. 7A, 8A, 9A and 10A are side cross-sectional images of ruthenium oxide layers that are formed on a ruthenium layer and are heat treated according to some embodiments of the present invention.

FIGS. 7B, 8B, 9B and 10B are top perspective images of ruthenium oxide layers that are formed on a ruthenium layer and are heat treated according to some embodiments of the present invention.

FIGS. 11A-11D graphically illustrate electrical characteristics of wrinkled layers according to some embodiments of the present invention.

FIGS. 12A-12F, 13A-13F, 14A-14F, 15A-15E, 16A-16F and 17A-17F are side cross-sectional views of integrated circuit electrodes according to various embodiments of the invention during intermediate fabrication steps according to various embodiments of the present invention.

FIGS. 18A-18D are top perspective images of ruthenium and ruthenium oxide layers before and after hydrogen annealing according to some embodiments of the present invention.

FIG. 19 graphically illustrates compositions of wrinkled layers according to some embodiments of the present invention.

FIG. 20 is a side cross-sectional image of a ruthenium/tantalum oxide/wrinkled ruthenium capacitor according to some embodiments of the present invention.

FIGS. 21A and 21B are side cross-sectional views of wrinkled ruthenium layers according to some embodiments of the present invention during intermediate fabrication steps according to embodiments of the present invention.

FIGS. 22A and 22B are top perspective images of a ruthenium layer and a wrinkled ruthenium layer respectively, according to some embodiments of the present invention.

FIGS. 23A and 23B are depth profiles of ruthenium layers prior to heat treatment and after heat treatment according to some embodiments of the present invention.

FIGS. 24A and 24B are side cross-sectional views of wrinkled ruthenium layers according to other embodiments of the present invention during intermediate fabrication steps according to other embodiments of the present invention.

### DETAILED DESCRIPTION OF PREFERRED EMBODIMENTS

The present invention now will be described more fully hereinafter with reference to the accompanying figures, in which embodiments of the invention are shown. This invention may, however, be embodied in many alternate forms and should not be construed as limited to the embodiments set forth herein.

Accordingly, while the invention is susceptible to various modifications and alternative forms, specific embodiments thereof are shown by way of example in the figures and will herein be described in detail. It should be understood, however, that there is no intent to limit the invention to the particular forms disclosed, but on the contrary, the invention is to cover all modifications, equivalents, and alternatives falling within the spirit and scope of the invention as defined by the claims. Like numbers refer to like elements throughout the description of the figures. In the figures, the dimensions of layers and regions may be exaggerated for clarity. It will also be understood that when an element, such as a layer, region or substrate, is referred to as being “on” another element, it can be directly on the other element or intervening elements may also be present. In contrast, when an element, such as a layer, region or substrate, is referred to as being “directly on” another element, there are no intervening elements present.

As was described above, it may be desirable to fabricate an integrated circuit electrode, such as a first (lower) electrode of an integrated circuit capacitor, from a noble metal, such as ruthenium, platinum and/or iridium, and/or an oxide thereof such as RuOx (i.e., RuO₂), PtOx (i.e., PtO₂) and/or IrOx (i.e., IrO₂), because these materials may not react with the dielectric layer of the capacitor and also may have a high work function. Dielectric layers for integrated circuit capacitors may include tantalum oxide and/or high dielectric constant material(s), such as SrTiO₃ (Ba, Sr)TiO₃ and/or (Pb, La)(Zr,Ti)O₃. Moreover, because ruthenium may be easy to pattern, ruthenium has been widely used in integrated circuit devices, such as DRAMs or ferroelectric random access memory devices (FRAM). Although ruthenium oxide films may exhibit varying electrical conductivities based on their oxygen content, they may be used as an electrode material. Moreover, since ruthenium oxide may have almost the same work function as ruthenium, it may have similar characteristics. For these and/or other reasons a lower electrode comprising ruthenium and a capacitor structure comprising, for example, Ru—Ta₂O₅—Ru, may be desirable for integrated circuit devices and fabrication processes.

Many techniques are known for forming a ruthenium oxide film. For example, ruthenium oxide may be formed by sputtering using a ruthenium metal target. Alternatively, a ruthenium organic source may be used to deposit ruthenium in an oxygen-containing ambient. Alternatively, a ruthenium layer may be formed on an integrated circuit substrate and oxidized, for example by heat treating in an oxygen-containing atmosphere, and/or exposing the ruthenium layer to an oxygen plasma. It is also known that when forming a ruthenium oxide film by reacting a ruthenium film in oxygen, the volume (thickness) of the ruthenium oxide film may be increased by the oxygen. For example, the ruthenium oxide film may have a volume that is about twice as large as the ruthenium film.

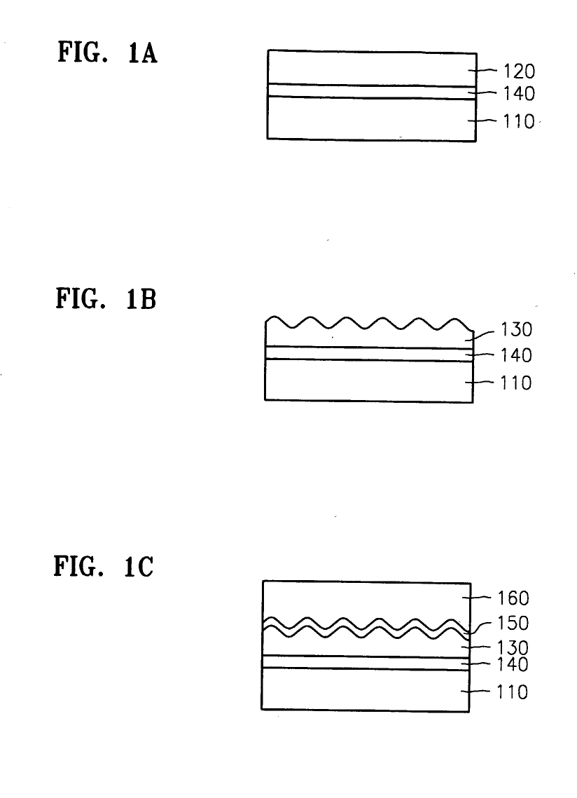

FIGS. 1A and 1B are cross-sectional views of integrated circuit electrodes according to some embodiments of the present invention during intermediate fabrication steps according to some embodiments of the invention. In particular, referring to FIG. 1A, a layer 120 comprising noble metal oxide such as ruthenium oxide is formed on an integrated circuit substrate 110. Then, in FIG. 1B, the layer comprising noble metal oxide is wrinkled by removing at least some oxygen from the layer comprising noble metal oxide, to thereby produce a wrinkled layer 130.

As shown in FIG. 1B, in some embodiments of the invention, wrinkling may be performed by exposing the layer comprising noble metal oxide to a reducing ambient, to thereby produce the wrinkled layer 130. The reduction reaction can be RuO₂+H₂=>Ru+H₂O. As also shown in FIGS. 1A and 1B, in some embodiments of the invention, wrinkling may be performed by deoxidizing the layer comprising noble metal oxide, to thereby produce the wrinkled layer 130. FIGS. 1A and 1B also provide an example of other embodiments of the invention, wherein wrinkling of a layer 120 comprising metal and another constituent is performed by removing at least some of the other constituent from the layer 120 comprising metal and another constituent, to thereby produce a wrinkled layer 130. Finally, FIGS. 1A and 1B also illustrate embodiments of the invention wherein a layer 120 comprising noble metal is wrinkled by decreasing the volume and/or thickness of the layer comprising noble metal on the integrated circuit substrate. Other embodiments will be described below.

The wrinkled layer 130 can provide an integrated circuit electrode according to some embodiments of the invention. This integrated circuit electrode may be used in many integrated circuit applications including as a first (lower or bottom) electrode of an integrated circuit capacitor FIG. 1C is a cross-sectional view of an integrated circuit capacitor that may be fabricated using a first electrode according to embodiments of the present invention. In particular, one or more dielectric layers 150 is provided on the wrinkled layer 130 opposite the substrate 110 and a second (upper or outer) electrode 160 is provided on the dielectric layer 150 opposite the wrinkled layer 130. Examples of dielectric layers 150 that can be used will be described below. The fabrication of dielectric layers 150 and upper electrodes 160 are well known to those having skill in the art and need not be described in further detail herein.

Referring again to FIGS. 1A and 1B, the substrate 110 may be a conventional integrated circuit substrate, such as a silicon semiconductor substrate. However, other conventional semiconductor materials, such as silicon carbide, gallium arsenide and/or gallium nitride, and/or non-semiconductor materials, such as glass, may be used. Moreover, the substrate may comprise a plurality of layers, such as one or more epitaxial layers on a base substrate, or one or more layers that are separated from a base substrate by an insulating layer, such as may be used in conventional semiconductor-on-insulator (SOI) technology. Many other substrate materials may be used.

Layer 120 may comprise a noble metal oxide, such as ruthenium oxide. As shown in FIG. 1B, by heat treating in a reducing atmosphere, oxygen contained in the ruthenium oxide layer 120 may be fully or partially exhausted, for example as oxygen or water vapor, so that the volume of the ruthenium oxide may be decreased gradually, thereby obtaining a wrinkled layer 130 that has an irregular surface. It will be understood that all of the oxygen may be removed, so that the wrinkled layer 130 that remains may consist essentially of noble metal. Alternatively, only some of the oxygen may be removed, so that the wrinkled layer 130 may also comprise noble metal and noble metal oxide.

Still referring to FIGS. 1A and 1B, one or more barrier layers 140 may be provided between the substrate 110 and the layer 120. This barrier layer may comprise the noble metal such as ruthenium, titanium nitride, tantalum oxide, silicon dioxide, silicon nitride and/or other conventional materials. Other embodiments will be described below. It will be understood that when the layer 120 is wrinkled, its volume decreases and its surface area increases to form the wrinkled layer 130. The barrier layer 140 may be exposed due to changes in the shape of the layer 120. In a capacitor application, this may allow the barrier layer to directly contact a dielectric layer 150 that is formed subsequently on the wrinkled layer 130. This may undesirably degrade the integrated circuit capacitor. Accordingly, in some embodiments of the invention, the layer 120 comprising noble metal oxide is wrinkled without uncovering an underlying region of the integrated circuit substrate directly beneath the wrinkled layer 130.

In other embodiments, the barrier layer 140 comprises a stable layer, the shape or volume of which may not change during the wrinkling step. This barrier layer may include a ruthenium layer. Thus, for example, a ruthenium layer may be formed and only partially oxidized, so that a ruthenium barrier layer lies beneath the ruthenium oxide layer 120.

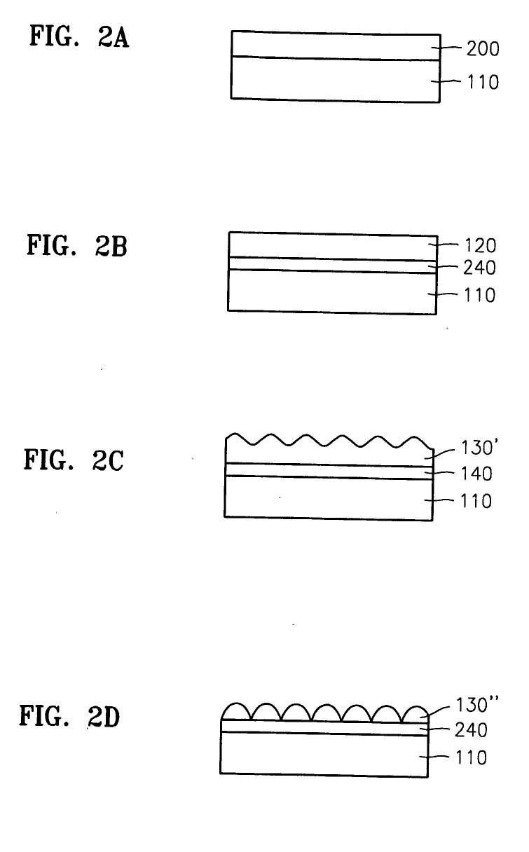

FIGS. 2A-2D are cross-sectional views of integrated circuit electrodes according to other embodiments of the invention during intermediate fabrication steps according to other embodiments of the invention. As shown in FIG. 2A, a ruthenium barrier layer 240 is formed on an integrated circuit substrate 110. Then, as shown in FIG. 2B, a layer 120 comprising a noble metal oxide such as ruthenium oxide, is formed on the barrier layer 240 comprising ruthenium. Finally, a dielectric layer and second electrode may be provided as was shown in FIG. 1C.

As shown in FIG. 2C, a partial reduction reaction can cause between about 30% to about 50% of the thickness of the ruthenium oxide layer 120 to be wrinkled to produce a wrinkled layer 130′. Moreover, as shown in FIG. 2D, up to 100% of the thickness of the ruthenium oxide layer 120 can be wrinkled in a full reduction to produce a wrinkled layer 130″. The partial wrinkling of FIG. 2C may occur by performing a partial reduction of the ruthenium oxide, so that only some of the oxygen is removed. The full wrinkling of FIG. 2D may be obtained by performing a full reduction of the ruthenium oxide, so that fully wrinkled layer 130″ consists essentially of ruthenium.

In either case, as shown in FIGS. 2C and 2D, the reduction reaction can cause the volume of the layer comprising ruthenium oxide 120 to be decreased, and the surface area to be increased, so that a wrinkled layer 130′, 130″ is formed. Moreover, as also shown in FIGS. 2A-2D, the underlying barrier layer 240 comprising Ru need not change in shape or volume during the reduction reaction, to thereby provide a barrier between the integrated circuit substrate 110 and the wrinkled layer 130′, 130″. The reduction in volume of an electrode comprising RuO₂ under a reducing atmosphere is described in a publication entitled “Hydrogen Reduction Properties of RuO₂ Electrodes” by Haritoni et al., Japanese Journal of Applied Physics, 38 L1275-L1277, Part II, No. 11A (Nov. 1, 1999), the disclosure of which is hereby incorporated by reference in its entirety as if set forth fully herein. As described therein, the thickness of a ruthenium oxide layer may be reduced between about 1.5 and about 3 times when the ruthenium oxide layer is reduced under various conditions. For example, a ruthenium oxide layer having an initial thickness of about 31.5 Ångstroms may be reduced to a ruthenium layer having thickness of about 13.6 Ångstroms. Accordingly, a reduction of about 2.3 times in thickness may be obtained.

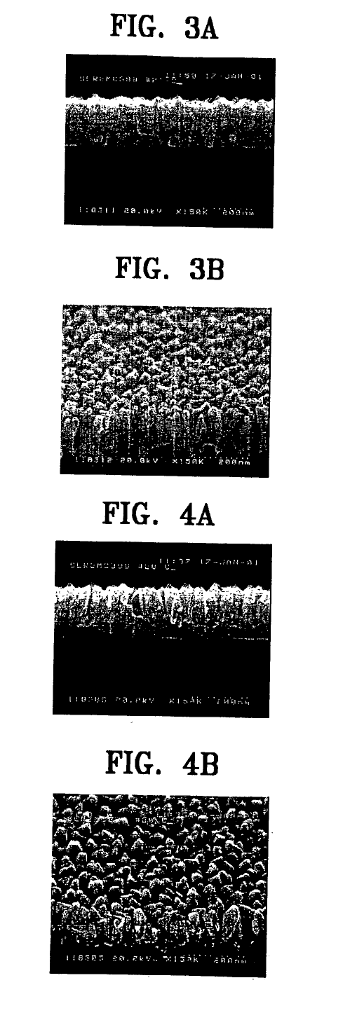

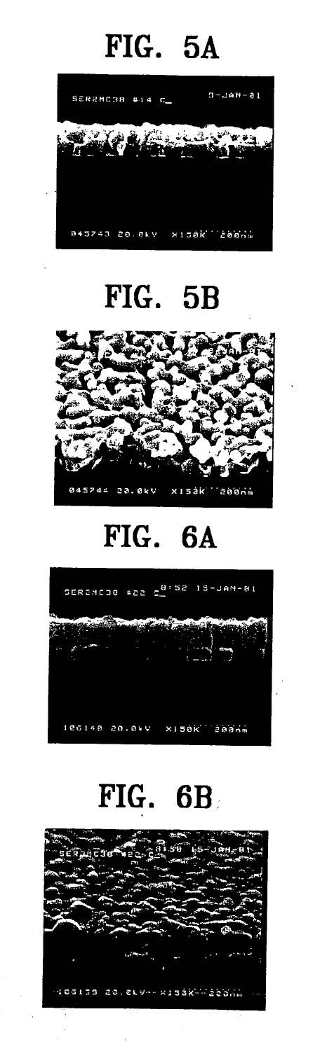

FIGS. 3A-6B are scanning electron microscope (SEM) images illustrating cross-sectional views (FIGS. 3A, 4A, 5A and 6A) and top perspective views (FIGS. 3B, 4B, 5B and 6B) of ruthenium oxide layers that were annealed in various ambient atmospheres according to some embodiments of the invention. In all of these FIGS. 3A-6B, a ruthenium layer was deposited on a silicon semiconductor substrate including tantalum oxide and silicon dioxide barrier layers thereon, using chemical vapor deposition. A ruthenium oxide layer then was deposited on the ruthenium layer using a separate chemical vapor deposition. FIGS. 3A and 3B illustrate annealing in a 100% N₂ ambient at 450° C. for thirty minutes. FIGS. 4A-4B illustrate annealing in vacuum (low pressure) at 450° C. for thirty minutes. FIGS. 5A-5B illustrate annealing in a 10% hydrogen ambient at 450° C. for thirty minutes. Finally, FIGS. 6A-6B illustrate annealing in 100% nitrogen at 700° C. for thirty minutes.

As shown in FIGS. 5A-5B, by treating in a hydrogen-containing ambient such as 10% hydrogen and 90% inert gas (e.g., nitrogen), a greater amount of wrinkling may be obtained compared to treating in a non-reducing ambient (FIGS. 3A-3B and 6A-6B) or in vacuum (FIGS. 4A-4B). Thus, in FIGS. 5A-5B, at least some of the oxygen contained in the ruthenium oxide layer appeared to be exhausted more effectively in the reducing ambient compared to being heat-treated in an inert atmosphere between 300° C. and 700° C. or under low pressure (for example, less than about 100 mTorr). Since the spaces between the crystalline grains in the ruthenium oxide layer of FIG. 5A are empty and columnar, it is reasonable to conclude that oxygen existing between the crystalline grains of the ruthenium oxide layer were exhausted during the heat treatment. As shown in FIGS. 3A-3B, 4A-4B and 6A-6B, the surface of the ruthenium oxide layer was either unchanged or little changed by nitrogen annealing or low pressure annealing.

In some embodiments of the present invention, the reducing ambient is a hydrogen-containing ambient. In other embodiments, the hydrogen-containing ambient consists of between about 1% and about 100% hydrogen and between about 0% to about 99% inert gas. The inert gases may comprise argon, nitrogen, helium and/or other inert gases. The inert gases can enhance the stability of the reaction that is performed in the hydrogen-containing reducing atmosphere. Other techniques for treating a lower electrode composed of ruthenium oxide in nitrogen diluted hydrogen to produce a ruthenium layer are described in Japanese Patent Application No. 11-150245 published Jun. 2, 1999 to Takeshi entitled Manufacture of Semiconductor Device.

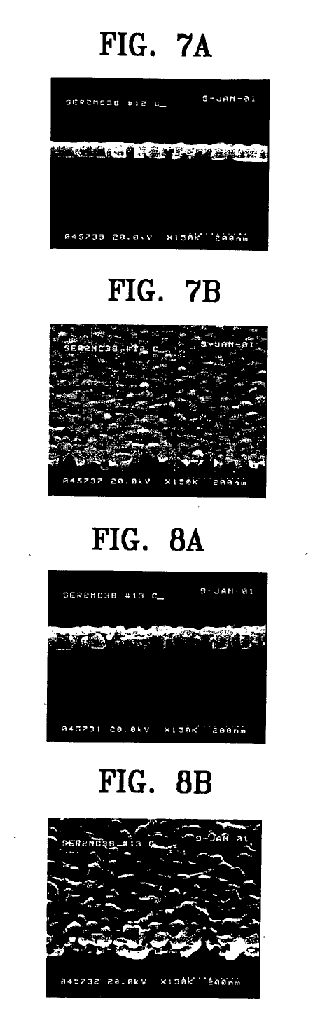

FIGS. 7A-10B are SEM images of ruthenium oxide layers of various thicknesses that are formed on a ruthenium layer and are heat-treated at a temperature of 450° C. at atmospheric pressure in an ambient of 10% hydrogen and 90% nitrogen for thirty minutes. FIGS. 7A, 8A, 9A and 10A are side cross-sectional views, and FIGS. 7B, 8B, 9B and 10B are top perspective views. As was the case in FIGS. 3A-6B, a ruthenium layer was deposited by chemical vapor deposition on a barrier layer of tantalum oxide and silicon dioxide that are on a silicon substrate, and a ruthenium oxide layer was deposited on the ruthenium layer by chemical vapor deposition. As shown in FIGS. 7A-10B, the underlying ruthenium layer is basically unchanged by the heat treatment in the reducing atmosphere. FIGS. 7A/7B, 8A/8B, 9A/9B and 10A/10B correspond to ruthenium oxide layers of 50 Å, 100 Å, 200 Å and 300 Å in thickness, respectively. As shown, as the thickness of the ruthenium oxide layer increases, the surface of the ruthenium oxide layer may become increasingly wrinkled. Stated differently, the thicker the ruthenium oxide layer, the more wrinkled the surface may become. It will be understood that wrinkling also can be a function of the degree of reduction (e.g., annealing time, temperature, hydrogen concentration, etc.).

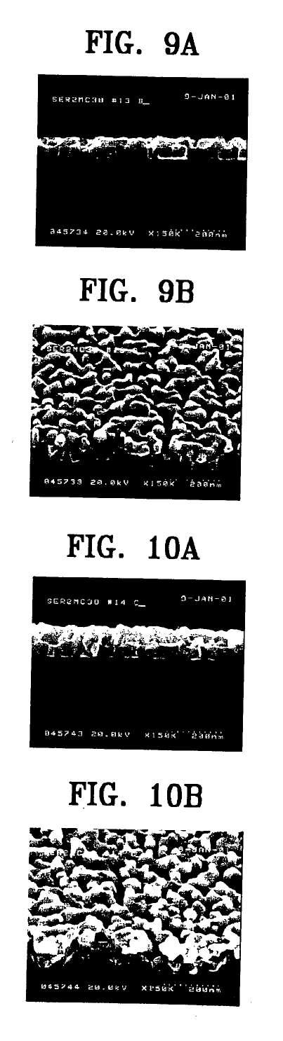

Thus, in FIGS. 7A-7B and 8A-8B in these experiments, for thicknesses of 50 Å and 100 Å, significant wrinkling may not occur. For a thickness of 200 Å (FIGS. 9A-9B), some wrinkling is evident. Moreover, in these experiments, for thicknesses of 300 Å or greater (FIGS. 10A-10B), the surface shape of the ruthenium oxide layer is almost the same as the surface shape of a hemispherical grain silicon film. Thus, it is possible to increase the capacitance considerably.

It has also been found, according to some embodiments of the invention, that it may be desirable for the thickness of the ruthenium oxide layer to be greater than that of the dielectric layer that is deposited thereon. For example, when the thickness of a dielectric layer comprising Ta₂O₅, Al₂O₃, TiO₂, BST and/or PZT is between about 20 Å and about 300 Å, the ruthenium oxide layer is between about 50 Å to about 400 Å in thickness in some embodiments of the invention.

In other embodiments, high dielectric materials, such as SrTiO₃, (Ba, Sr)TiOx and/or (Pt, La)(Zr, Ti)O₃, may be used. However, even if a conventional tantalum oxide (Ta₂O₅) dielectric layer is used, which has a relatively low dielectric constant, it is possible to obtain an equivalent oxide thickness of about 6 Å. As understood by those having skill in the art, equivalent oxide thickness is the equivalent thickness converted into silicon dioxide under the same capacitance.

In order to investigate electrical characteristics of integrated circuit capacitors that are fabricated according to some embodiments of the present invention, integrated circuit capacitors according to some embodiments of the invention were manufactured as follows: A silicon dioxide layer was deposited on a silicon semiconductor wafer and a tantalum oxide layer was deposited on the silicon dioxide layer. A wide range of conventional thicknesses may be used. A ruthenium layer having a thickness of about 200 Å was formed by chemical vapor deposition on the tantalum oxide layer. A ruthenium oxide layer having a thickness of between about 100 Å and about 300 Å was deposited by chemical vapor deposition on the ruthenium layer. The ruthenium oxide layers were deposited to have different thicknesses, so that each of the wrinkled layers can exhibit different surface wrinkling. The ruthenium oxide layer was heat treated in a reducing atmosphere of 10% hydrogen at 450° C. for thirty minutes, to wrinkle the ruthenium oxide layer. A tantalum oxide dielectric layer of thickness of between about 110 Å and about 150 Å was deposited on the wrinkled layer. The tantalum oxide layer was then heat treated in nitrogen at 700° C. for thirty minutes, to crystallize the tantalum oxide layer. Finally, a ruthenium upper electrode was chemical vapor deposited on the tantalum oxide dielectric layer to a thickness of about 500 Å.

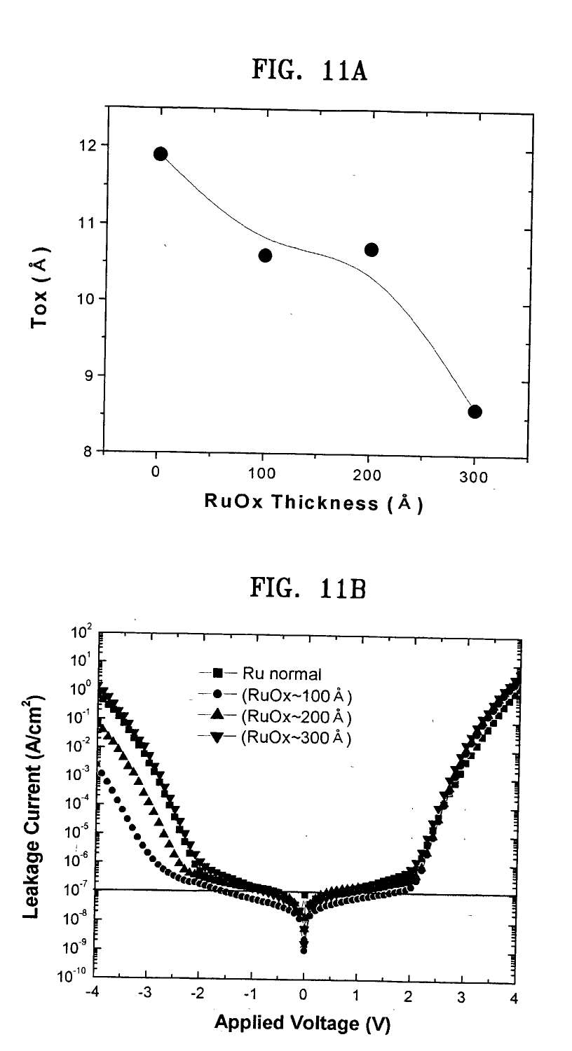

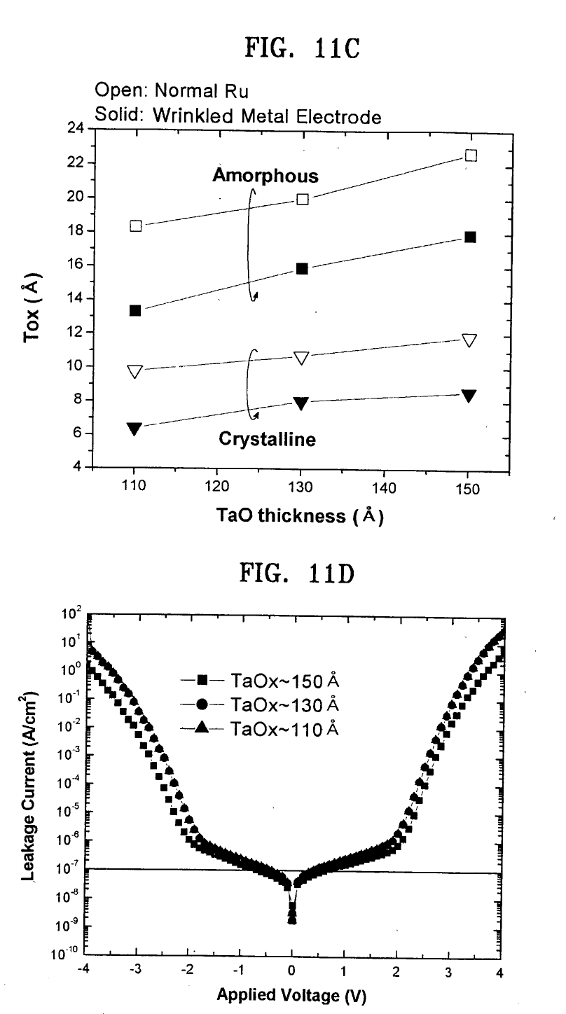

FIG. 11A graphically illustrates the equivalent silicon dioxide thickness of the wrinkled layer as a function of the original thickness of the ruthenium oxide layer of 0 Å, 100 Å, 200 Å and 300 Å. FIG. 11B graphically illustrates leakage current as a function of the thickness of the wrinkled layer that is formed from an original ruthenium oxide layer of 0 Å, 100 Å, 200 Å and 300 Å in thickness.

Referring to FIGS. 11A and 11B, as the thickness of the ruthenium oxide layer increases, the surface wrinkling of the ruthenium oxide layer became more severe and, thus, the effective thickness of the ruthenium oxide layer is decreased. Equivalent silicon dioxide thickness as low as about 6 Å or lower may be obtained. It will be understood that the effective thickness Tₒₓ=(3.9ε₀A)/C where ε₀ is the dielectric constant of vacuum and is equal to 8.85×10⁻¹² F/m, A is the area of the capacitor and C is the capacitance of the capacitor. In addition, as shown in FIG. 11B, as the degree of wrinkling of the surface of the structure increased, the leakage current increased. However, compared to a conventional ruthenium capacitor in which a wrinkled layer is not formed (Ru normal in FIG. 11B), wrinkled capacitors according to embodiments of the invention can have a lower leakage current.

Stated differently, FIG. 11A illustrates that the effective thickness is decreased as a function of the increasing ruthenium oxide thickness due to the increased surface wrinkling. Moreover, FIG. 11B illustrates that the leakage currents gradually increase as a function of increasing ruthenium oxide thickness. This increase in leakage current may be explained by the effects of hydrogen annealing on the ruthenium metal layer. In any event, the leakage current of the wrinkled layer was lower than that of a conventional ruthenium layer.

FIGS. 11C and 11D graphically illustrate electrical characteristics of these capacitors, each of which has a different tantalum oxide dielectric layer thickness, wherein the ruthenium oxide layer has a fixed thickness of 300 Å. In particular, FIG. 11C graphically illustrates equivalent oxide thickness versus tantalum oxide thickness for conventional ruthenium electrodes (open squares and triangles) and wrinkled ruthenium oxide electrodes (solid squares and triangles) where the squares indicate amorphous tantalum oxide and the triangles indicate crystalline tantalum oxide. As shown in FIG. 11C, when the tantalum oxide dielectric layer was deposited on the wrinkled electrodes, the surface had almost the same surface wrinkling and, as the deposition thickness of tantalum oxide was decreased, the surface area that can be obtained was increased. Accordingly, as the thickness of the tantalum oxide decreases, the equivalent oxide thickness decreases. Moreover, as shown in FIG. 11D, when the thickness of the tantalum oxide dielectric layer is in the range between about 110 Å and about 150 Å, the leakage current is unchanged or changes very little.

Based on the results of FIGS. 11A-11D, in some embodiments of the present invention, in order to apply a wrinkled electrode structure to a conventional integrated circuit memory device, the wrinkling of the surface of the ruthenium oxide layer may be maximized, but not to the extent that adjacent memory cells are directly in contact with one another. In addition, in some embodiments, the dielectric layer thickness may be minimized, but not to the extent that the device characteristics of the memory deteriorate. Finally, FIGS. 11C and 11D illustrate that the equivalent oxide thickness can be decreased to as low as 6 Å in some embodiments of the invention, without the need to use high dielectric constant materials.

According to some embodiments of the invention, the wrinkled layer includes a plurality of subhemispherical (i.e., less than a hemisphere) noble metal protrusions. In other embodiments, the wrinkled layer consists essentially of subhemispherical noble metal protrusions. In still other embodiments, the wrinkled layer is substantially free of superhemispherical (i.e., more than a hemisphere) noble metal protrusions. Stated differently, in some embodiments of the present invention, the wrinkled layer does not have a negative slope. This may contrast sharply with conventional hemispherical grain silicon electrode structures, wherein superhemispherical protrusions generally are found so that a negative slope is present over at least some portion of the superhemispherical protrusions. Since wrinkled layers according to some embodiments of the present invention can be free of superhemispherical protrusions, it may be easier to deposit a dielectric layer thereon with good step coverage. Moreover, the superhemispherical projections of conventional hemispherical grain silicon may cause adjacent grains to come into contact with one another, and thereby short circuit adjacent memory cells. In contrast, since a ruthenium oxide layer according to some embodiments of the invention is deposited to a predetermined thickness and then the volume and/or thickness is decreased, there can be little or no contact defects between the cells. Accordingly, wrinkling processes and wrinkled electrodes according to some embodiments of the present invention may have advantages compared to conventional hemispherical grain silicon fabrication processes and electrodes.

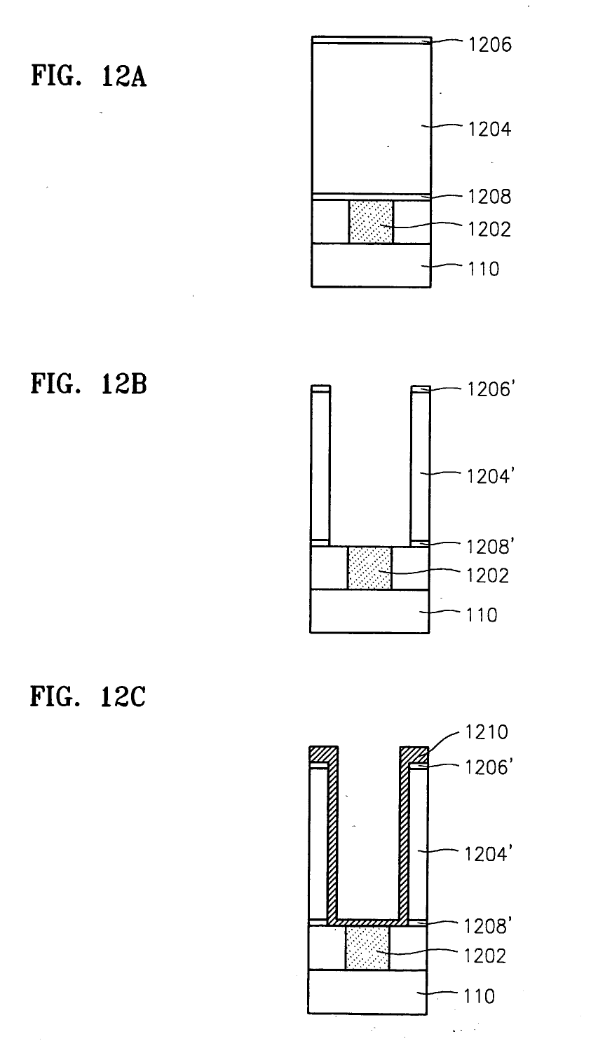

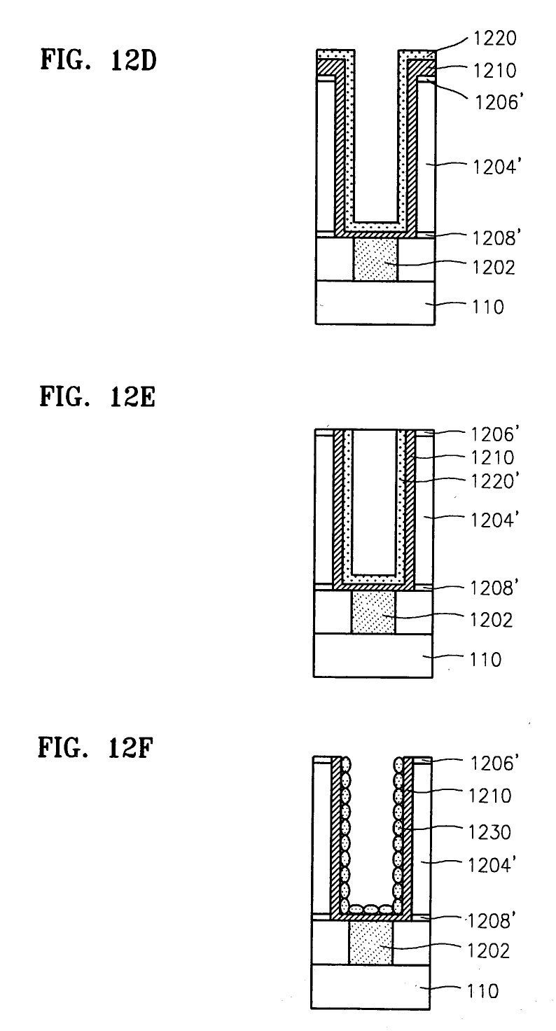

FIGS. 12A-12F, 13A-13F, 14A-14F, 15A-15E and 16A-16F and 17A-17F are side cross-sectional views of integrated circuit electrodes according to various embodiments of the invention during intermediate fabrication steps according to various embodiments of the present invention. In these embodiments, a first or lower electrode for an integrated circuit capacitor is formed by wrinkling a layer that comprises a noble metal oxide, such as ruthenium oxide, by removing at least some oxygen from the layer, to thereby produce a wrinkled layer. In these embodiments, the layer of ruthenium oxide may be formed by chemical vapor deposition, sputtering, by heat treating a ruthenium layer in an oxidizing atmosphere, for example at a temperature of 450° C. or greater, and/or by exposing the surface of a ruthenium layer to oxygen plasma. Other conventional techniques of forming a ruthenium oxide layer also may be used. When forming a ruthenium layer, a conventional Ru(EpCp)₂ metalorganic source and/or other conventional ruthenium source may be used. In FIGS. 12A-17F, the subsequent formation of a dielectric layer on the lower electrode and the formation of an upper electrode on the dielectric layer are not shown for simplicity. However, as was already described in connection with FIG. 1C, these layers may be formed via conventional techniques.

FIGS. 12A-12F are side cross-sectional views of integrated circuit electrodes according to some embodiments of the invention during intermediate fabrication steps according to some embodiments of the invention. In FIGS. 12A-12F, a concave-type electrode, for example for a Ru/TaOx/Ru capacitor, is manufactured. Referring now to FIG. 12A, a contact plug 1202 is formed on an integrated circuit substrate 110 and a dielectric layer 1204 and a cap 1206 are formed on the contact plug using conventional techniques. The dielectric layer 1204 also may be referred to as a mold oxide. The cap 1206 also may be referred to as a sacrificial oxide layer. An etch stop layer 1208 also may be formed.

In FIG. 12B, the cap 1206, the dielectric layer 1204 and the etch stop 1208 are patterned to form a patterned cap 1206′, a patterned dielectric layer 1204′ and a patterned etch stop 1208′, using conventional photolithography.

Referring now to FIG. 12C, a ruthenium layer 1210 is conformally deposited, for example by chemical vapor deposition. Then, referring to FIG. 12D, a ruthenium oxide layer 1220 is formed on the ruthenium layer 1210, for example by chemical vapor deposition. Then, in FIG. 12E, the top surfaces of the ruthenium oxide layer 1220 and the ruthenium layer 1210 are etched back using the patterned cap 1206′ as an etch stop. Thus, a patterned ruthenium layer 1210′ and a patterned ruthenium oxide layer 1220′ that line the patterned dielectric layer 1204′ are formed in FIG. 12E.

Referring now to FIG. 12F, the patterned ruthenium oxide layer 1220′ is heat treated in a reducing atmosphere to produce a wrinkled ruthenium layer 1230. In FIG. 12F, all of the oxygen may be removed from the patterned ruthenium oxide layer 1220′, to produce a wrinkled ruthenium layer 1230. A capacitor dielectric layer and a second (upper) electrode then may be formed using conventional techniques to complete a capacitor.

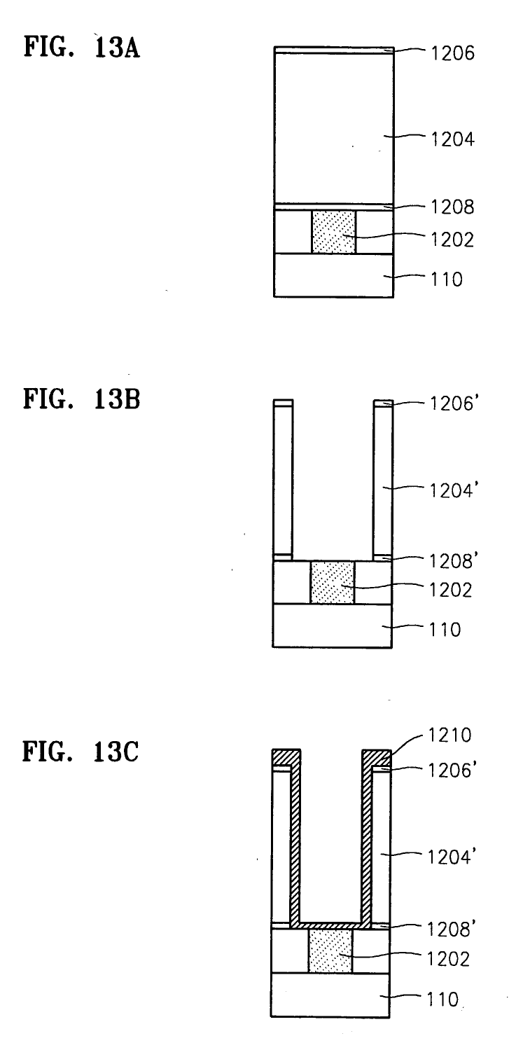

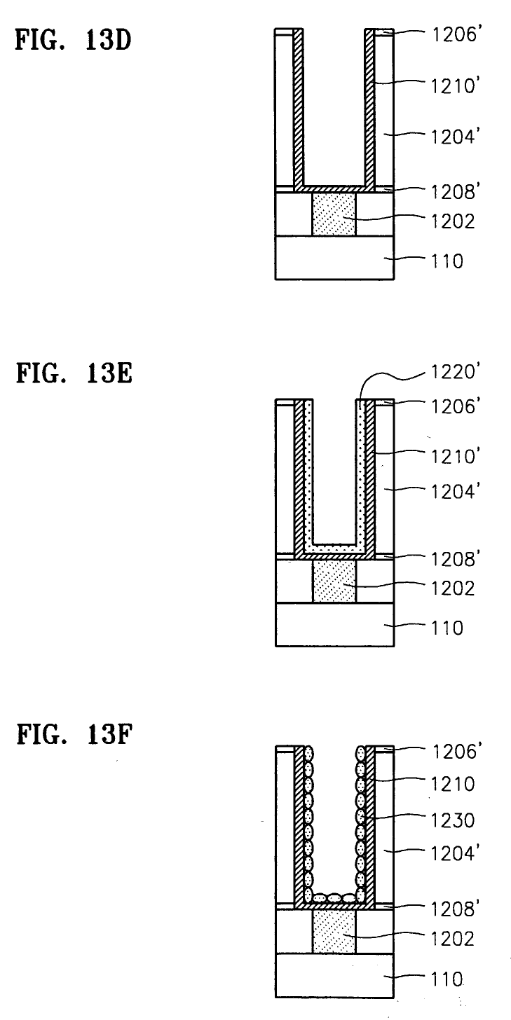

FIGS. 13A-13F are side cross-sectional views of integrated circuit electrodes according to other embodiments of the invention during intermediate fabrication steps according to other embodiments of the invention. FIGS. 13A-13C correspond to FIGS. 12A-12C and a description thereof will not be repeated for the sake of brevity. Referring now to FIG. 13D, the ruthenium layer 1210 is etched back to form a patterned ruthenium layer 1210′ that lines the trench in the dielectric layer 1204′. Then, referring to FIG. 13E, the surface of the patterned ruthenium layer 1210′ is heated, for example in an oxygen atmosphere, to oxidize the surface of the patterned ruthenium layer 1210′ and, thus, form a patterned ruthenium oxide layer 1220″. Alternatively, the patterned ruthenium layer 1210′ may be exposed to a plasma containing oxygen. Other techniques also may be used. Then, in FIG. 13F, the patterned ruthenium oxide layer 1220″ is heated in a reducing atmosphere to wrinkle the ruthenium oxide layer by removing at least some oxygen from the patterned ruthenium oxide layer, to thereby produce a wrinkled layer 1230. A dielectric layer and second (upper) electrode then may be formed using conventional techniques.

It will be understood that the sequence of operations performed in FIGS. 13E and 13F may be reversed. For example, a ruthenium oxide layer (not shown) may be formed on the wrinkled layer 1230 between the step of forming the wrinkled layer 1230 and the step of forming the dielectric layer.

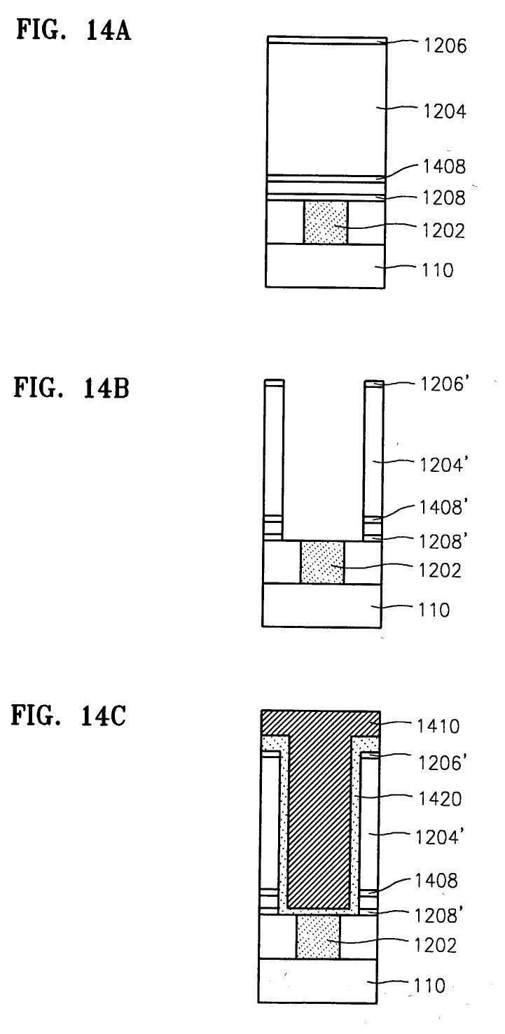

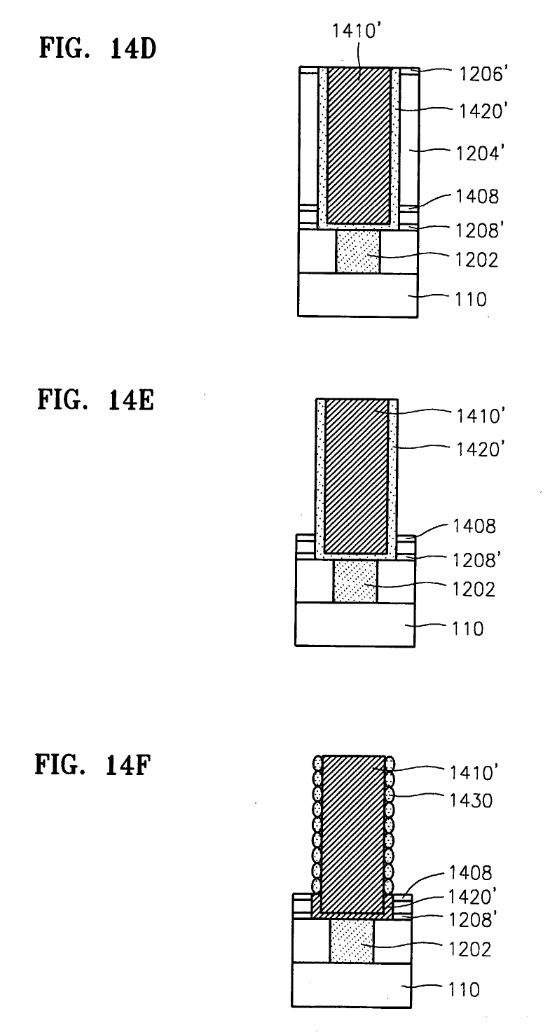

FIGS. 14A-14F are side cross-sectional views of integrated circuit electrodes according to other embodiments of the present invention during intermediate fabrication steps according to other embodiments of the present invention. In FIGS. 14A-14F, an electrode for a stack type capacitor (for example, a stack type Ru/TaOx/Ru capacitor) is fabricated. Referring to FIG. 14A, a sacrificial oxide layer 1206, a mold oxide 1204, an etch stop layer 1208, a second etch stop layer 1408, and a contact plug 1202 are fabricated on an integrated circuit substrate 110 using conventional techniques. In FIG. 14B, the mold oxide 1204 is patterned to form a capacitor node. 30 Referring now to FIG. 14C, a ruthenium oxide layer 1420 is then conformally deposited, for example by chemical vapor deposition. A ruthenium layer 1410 is then formed on the ruthenium oxide layer 1420, for example by chemical vapor deposition.

Then, in FIG. 14D, the ruthenium oxide layer 1420 and ruthenium layer 1410 are etched back using the patterned sacrificial oxide layer 1206′ to form a patterned ruthenium oxide layer 1420′ and a patterned ruthenium layer 1410′. Then, in FIG. 14E, the patterned mold oxide 1204′ is removed, for example by wet etching, to form a stacked storage node, using the patterned second etch stop layer 1408′. Finally, in FIG. 14F, the stacked storage node is heated in a reducing atmosphere to wrinkle the patterned layer comprising ruthenium oxide 1420′, for example to remove all of the oxygen therefrom, and thereby produce a wrinkled ruthenium layer 1430. A dielectric layer and second (upper) electrode then may be formed using conventional techniques.

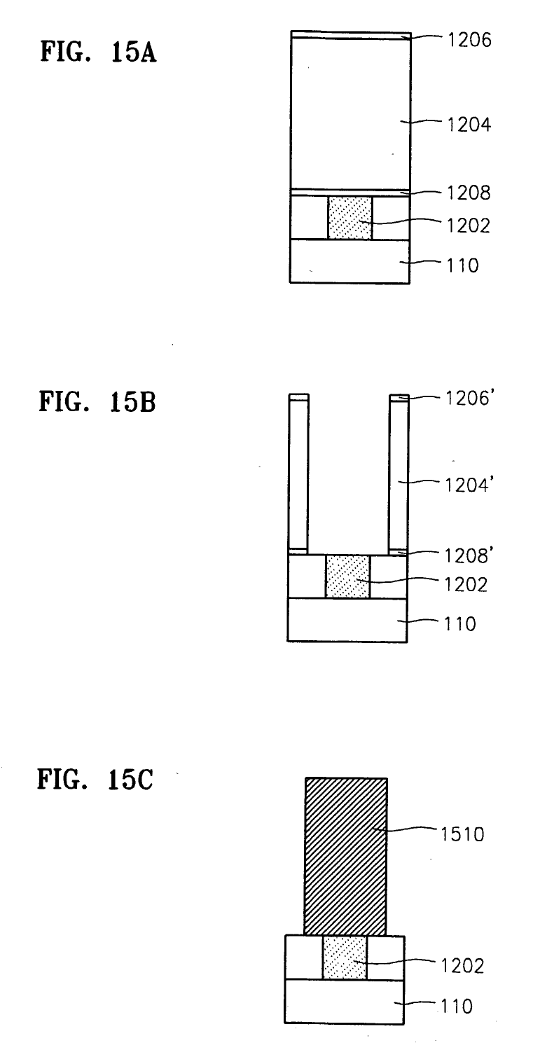

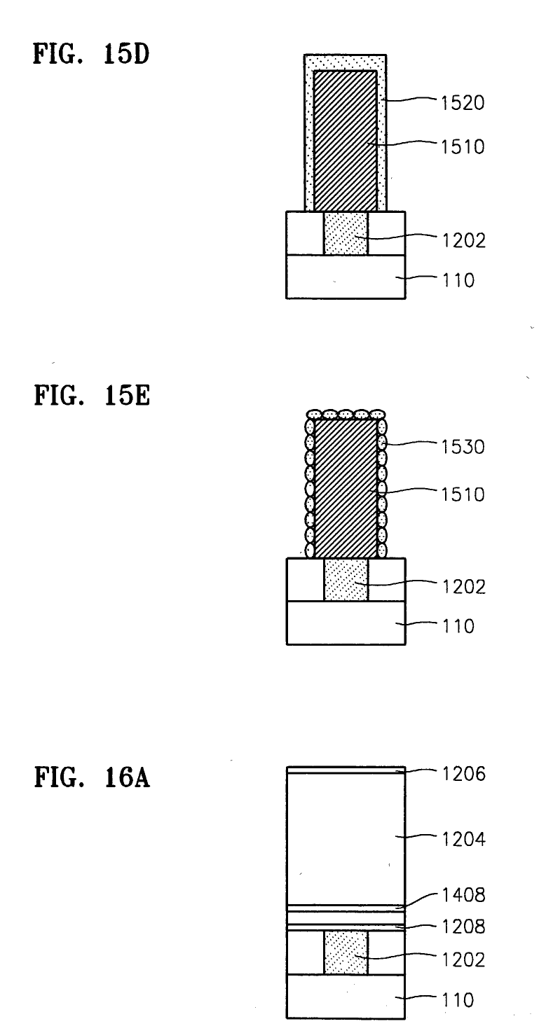

FIGS. 15A-15E illustrate integrated circuit electrodes according to other embodiments of the present invention during intermediate fabrication steps according to other embodiments of the present invention. In FIGS. 15A-15E, an electrode for a stack type capacitor such as a stack type Ru/TaOX/Ru capacitor, is fabricated. The operations of FIGS. 15A and 15B correspond to FIGS. 12A and 12B and a description thereof will not be repeated for the sake of brevity. Then, as shown in FIG. 15C, a ruthenium layer 1510 is deposited, for example by chemical vapor deposition and etched back using the sacrificial oxide layer 1206′. Then the patterned mold oxide layer 1204′ is removed, for example by wet etching, to form a stacked storage node.

Then, in FIG. 15D, the surface of the ruthenium layer 1510 is heat treated in an oxygen atmosphere and/or exposed to a plasma containing oxygen to oxidize the surface of the ruthenium layer to form a ruthenium oxide layer 1520. Finally, in FIG. 15E, a wrinkled ruthenium layer 1530 is formed from the ruthenium oxide layer 1520 by heat treating in a reducing atmosphere, to remove all of the oxygen from the ruthenium oxide layer. A dielectric layer and second (upper) electrode then may be formed using conventional techniques.

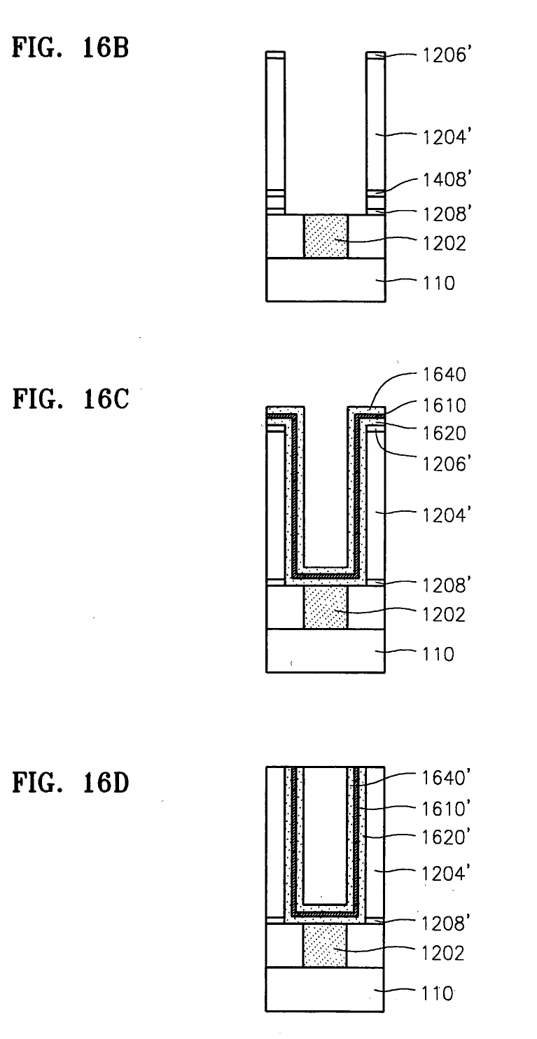

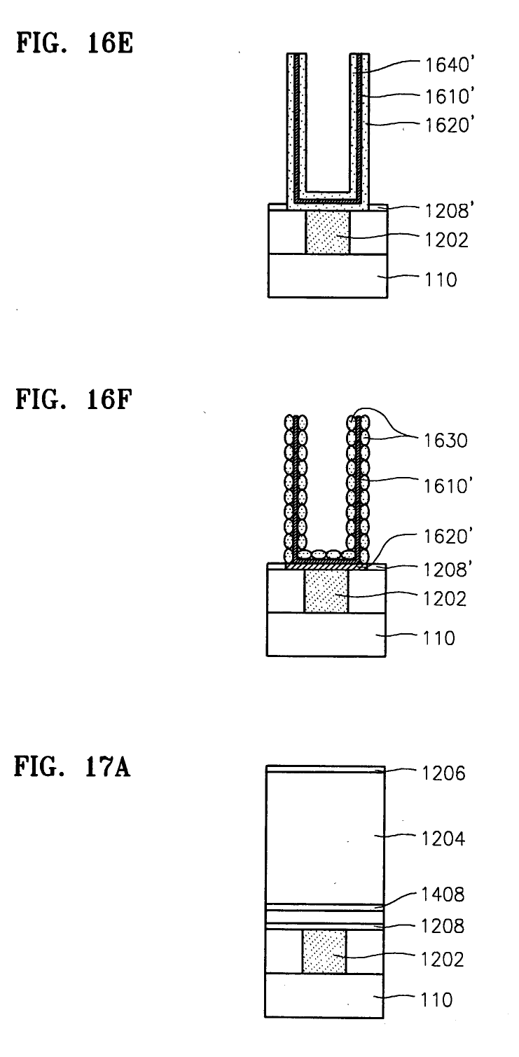

FIGS. 16A-16F illustrate other integrated circuit electrodes according to other embodiments of the present invention during intermediate fabrication steps according to other embodiments of the present invention. Embodiments of FIGS. 16A-16F may be used to form an electrode for a cylinder-type capacitor such as a Ru/TaOx/Ru cylinder-type capacitor. The operations of FIGS. 16A and 16B correspond to FIGS. 12A and 12B and will not be repeated for the sake of brevity.

Referring now to FIG. 16C, a first ruthenium oxide layer 1620 is conformally deposited by chemical vapor deposition. A ruthenium layer 1610 then is deposited on the first ruthenium oxide layer 1620, for example by chemical vapor deposition. A second ruthenium oxide layer 1640 then is deposited on the ruthenium layer 1610 by chemical vapor deposition. In FIG. 16B, the ruthenium and ruthenium oxide layers 1610, 1620 and 1640 then are etched back using the sacrificial oxide layer 1206′ to form a first patterned ruthenium oxide layer 1620′, a patterned ruthenium layer 1610′ and a second patterned ruthenium oxide layer 1640′.

Referring now to FIG. 16E, the patterned mold oxide 1204′ is then removed, for example by a wet etching, to form a cylinder-type storage node. Finally, referring to FIG. 16F, the surface of the first and second ruthenium layers 1620′ and 1640′ are then heat treated in a reducing atmosphere, to thereby form a wrinkled ruthenium layer 1630 on both sides of the patterned ruthenium layer 1610′. A dielectric layer and second (upper) electrode then may be formed using conventional techniques.

According to other embodiments of the invention, the first layer 1620 and the second layer 1640 may be of different compositions from one another in FIG. 16C. Thus, upon heat treatment in FIG. 16F, differing amounts of wrinkling may be obtained for the wrinkled layer 1630 on either side of the patterned ruthenium layer 1610′. Differential wrinkling may be obtained, according to some embodiments of the present invention, by using different noble metals for each of the first and second layers 1620′, 1640′. In other embodiments, differential wrinkling may be obtained by changing the relative oxygen component “x” in the RuOx. For example, in some embodiments, as the “x” increases, the wrinkling may increase and as “x” decreases, the wrinkling may decrease (the surface becomes smoother).

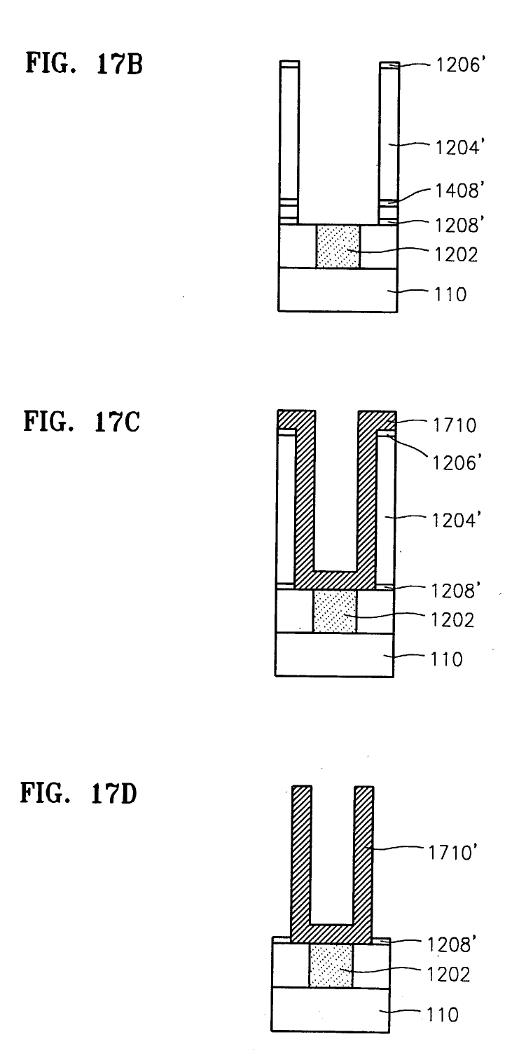

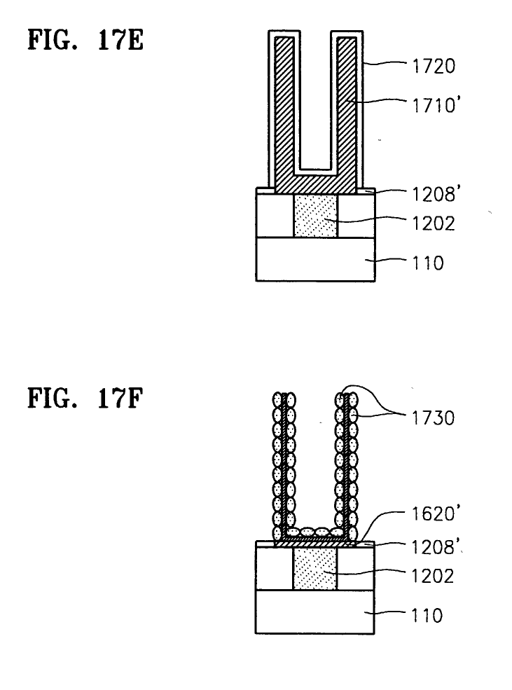

FIGS. 17A-17F illustrate other embodiments of integrated circuit electrodes according to other embodiments of the present invention during intermediate fabrication steps according to other embodiments of the present invention. The operations of FIGS. 17A-17F may be used to fabricate an electrode for a cylinder-type capacitor, such as a cylinder-type RuOx/Ru/RuOx capacitor, according to embodiments of the present invention. The operations of FIGS. 17A and 17B correspond to FIGS. 16A and 16B, and will not be described again for the sake of brevity.

Then, referring to FIG. 17C, a ruthenium layer 1710 is deposited by chemical vapor deposition and then etched back using the sacrificial oxide layer 1206′ to form a patterned ruthenium layer. Referring now to FIG. 17D, the mold oxide layer is then etched away, for example by wet etching, so that the patterned ruthenium layer 1710′ forms a cylinder-type ruthenium storage node. Then, referring to FIG. 17E, the surface of the patterned ruthenium layer 1710′ is heated in an oxygen atmosphere and/or exposed to an oxygen-containing plasma, to oxidize the surface of the patterned ruthenium layer 1710′ and thereby form a ruthenium oxide layer 1720. Finally, referring to FIG. 17F, the structure is then heated in a reducing atmosphere to remove all of the oxide from the ruthenium oxide layer 1720 to form a wrinkled layer 1730 comprising ruthenium. A dielectric layer and second (upper) electrode then may be formed using conventional techniques.

In yet other embodiments of the present invention, a cylinder-type capacitor may be fabricated wherein the inner cylinder surface comprises a wrinkled ruthenium layer, but the outer cylinder surface comprises a smooth ruthenium layer or a ruthenium layer that is wrinkled less than the inner cylinder surface. More specifically, in these embodiments, at FIG. 17D, the mold oxide layer is not etched away but, rather, remains, so that in FIG. 17D, the patterned ruthenium layer 1710′ only is formed on the inner surface of the cylinder-type ruthenium storage node. In FIG. 17E, the surface of the patterned ruthenium layer 1710′ is heated in an oxygen atmosphere, and/or exposed to an oxygen-containing plasma, to oxidize the surface of the patterned ruthenium layer 1710′, and thereby form a ruthenium oxide layer 1720 on the inner surface of the cylinder. Since the mold oxide 1204 was not removed from the outer surface of the cylinder, the outer surface is not wrinkled but, rather, is smooth. Thus, in these embodiments, contact between adjacent devices can be reduced or prevented.

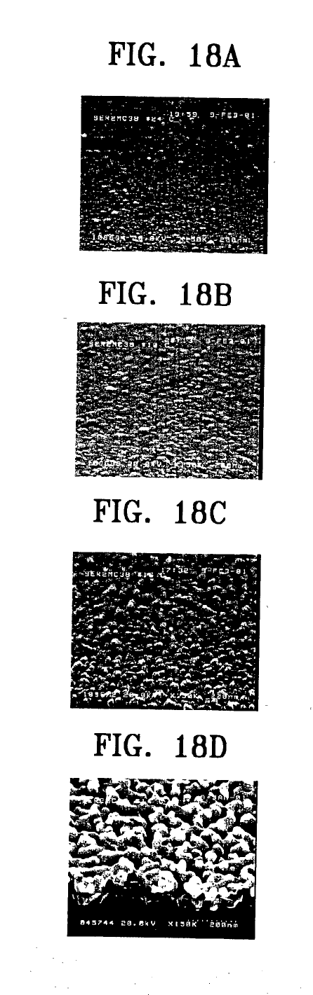

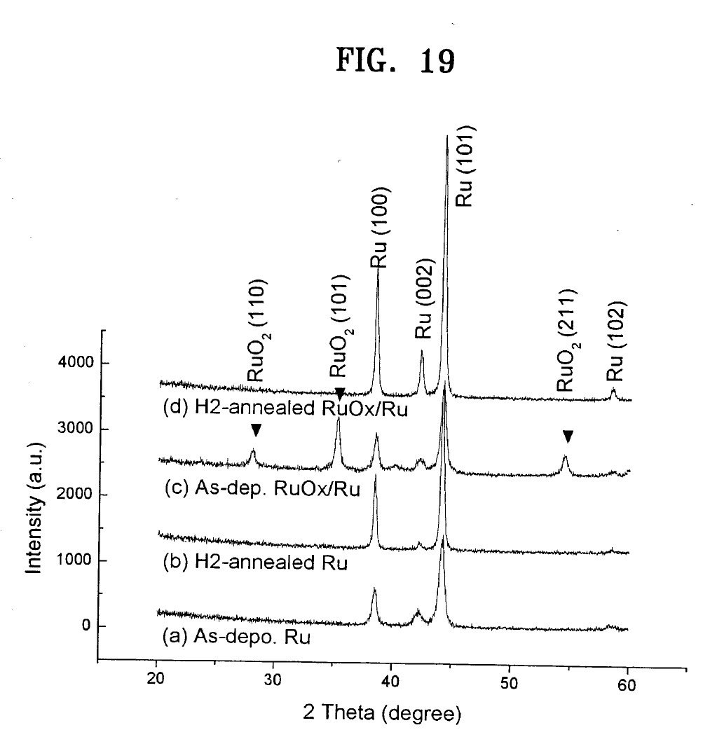

Other examples that illustrates wrinkling of a ruthenium oxide layer according to embodiments of the present invention now will be provided. To obtain these examples, ruthenium oxide films were deposited on a TaOx/SiO₂/Si substrate by chemical vapor deposition using Ru(EtCp)₂:bis-(ethylcyclopentadieny)ruthenium precursors and annealed at 450° C. for 30 minutes in 90% N₂-10% H₂. FIGS. 18A-18D are top perspective SEM images of Ru and RuOx/Ru films before (FIGS. 18A and 18C) and after (18B and 18D) hydrogen annealing. As shown in FIGS. 18A and 18B, the morphology of Ru films was almost constant regardless of hydrogen annealing. In contrast, as shown in FIGS. 18C-18D, RuOx films were dramatically wrinkled by hydrogen annealing. From x-ray diffraction (XRD) analysis shown in FIG. 19, the wrinkled films were identified as ruthenium metal films that were formed by reduction of ruthenium oxide films.

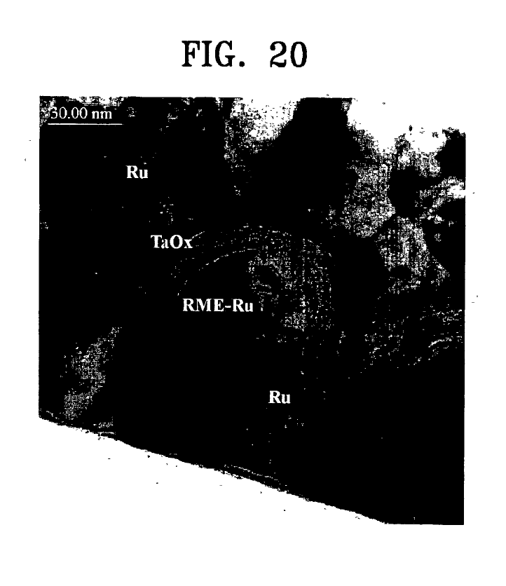

FIG. 20 is a Transmission Electron Microscope (TEM) image of a wrinkled Ru/TaOx/Ru capacitor. As shown in this embodiment, the wrinkled ruthenium layer provides subhemispherical ruthenium protrusions. Thus, in this embodiment, the wrinkled ruthenium layer does not have the negative slope that is associated with hemispherical grain silicon structures. This lack of a negative slope in some embodiments of the invention can improve the conformal step coverage of dielectric films and/or reduce reliability problems as was already described.

Embodiments of the invention that were described above have wrinkled a layer comprising noble metal oxide by removing at least some oxygen from the layer comprising noble metal oxide, to thereby produce a wrinkled layer. Other embodiments for producing a wrinkled layer now will be described. In these embodiments, an integrated circuit electrode is fabricated by forming a layer comprising metal and another constituent other than oxygen on an integrated circuit substrate. The layer comprising metal and another constituent other than oxygen is then wrinkled by removing at least some of the other constituent from the layer comprising metal and another constituent other than oxygen, to thereby produce the wrinkled layer. In particular, in some embodiments, it has been realized that if a noble metal layer is deposited by chemical vapor deposition, the noble metal layer may contain a considerable number of carbon atoms. These carbon atoms can be effectively exhausted by heat treatment. When the carbon atoms are exhausted, the volume of the noble metal layer decreases and, as a result, the surface of the noble metal layer may become wrinkled.

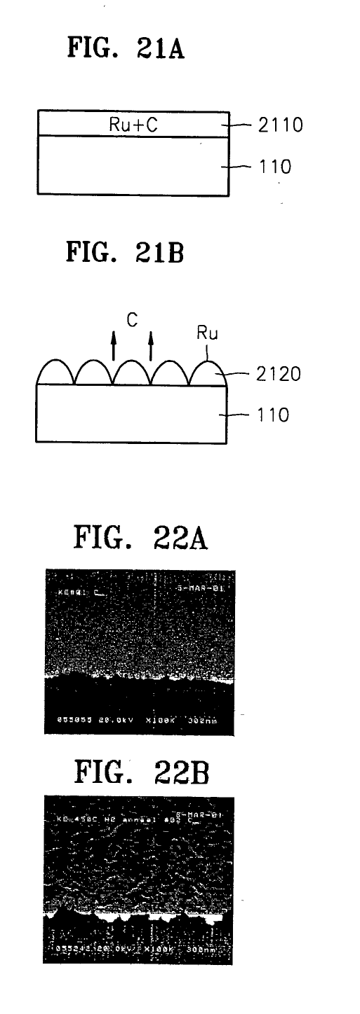

Thus, referring to FIG. 21A, a layer 2110 comprising ruthenium is formed on an integrated circuit substrate 110. An intervening layer of silicon dioxide and/or other materials also may be formed. As shown in FIG. 21A, the layer 2110 comprising ruthenium also contains a considerable number of carbon atoms. Then, referring to FIG. 21B, heat treatment is performed, for example at 450° C. in hydrogen, to exhaust, the carbon atoms and reduce the volume of ruthenium layer 2110 to provide a wrinkled layer 2120 comprising ruthenium.

FIG. 22A is an SEM image of a top perspective view of a ruthenium layer having a thickness of 250 Å that is formed on a silicon dioxide layer on a silicon substrate. As shown, the morphology is not wrinkled. In sharp contrast, FIG. 22B illustrates the ruthenium layer after an anneal at 450° C. in hydrogen for 30 minutes, illustrating that the thickness decreases to about 150 Å, and a wrinkled layer is formed.

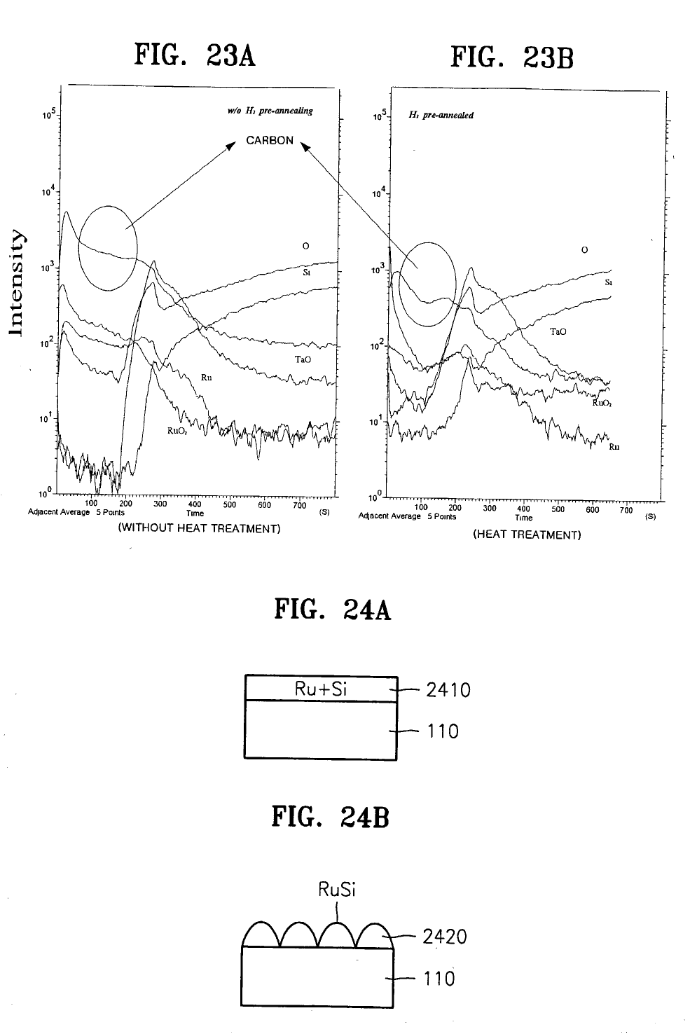

FIGS. 23A and 23B are SIMS depth profiles of the ruthenium layer prior to heat treatment (FIG. 22A) and after heat treatment (FIG. 22B). As shown, the carbon concentration of FIG. 23A decreases markedly in FIG. 23B after heat treatment. Accordingly, a layer comprising metal and another constituent other than oxygen can be wrinkled by removing at least some of the other constituent from the layer, to thereby produce a wrinkled layer.

FIGS. 24A and 24B illustrate yet other embodiments of the present invention. In these embodiments, a layer comprising metal and another constituent is formed on an integrated circuit substrate. The layer comprising metal and another constituent is then wrinkled by reacting at least some of the metal with at least some of the other constituent, to form a compound of the metal and the other constituent, and thereby produce a wrinkled layer.

In the embodiments shown in FIGS. 24A and 24B, the metal comprises a noble metal such as ruthenium, and the other constituent comprises silicon. The wrinkling comprises heat treating a layer comprising noble metal and silicon, to react at least some of the noble metal with at least some of the silicon to form a noble metal silicide.

Thus, as shown in FIG. 24A, a layer 2410 that comprises ruthenium and silicon is formed on an integrated circuit substrate 110. An anneal is then performed, for example at 450° C. in nitrogen for thirty minutes, to react the ruthenium and the silicon, and thereby form a wrinkled layer 2420 comprising ruthenium silicide (RuSi). As shown in FIG. 24B, due to the volume decrease in forming the compound, the wrinkled layer 2420 comprising ruthenium silicide is then formed. It will be understood that additional silicon may be provided in the ruthenium layer using diffusion and/or other techniques. However, as was already shown in FIGS. 23A and 23B, silicon already may be present in a ruthenium layer.

In the drawings and specification, there have been disclosed typical preferred embodiments of the invention and, although specific terms are employed, they are used in a generic and descriptive sense only and not for purposes of limitation, the scope of the invention being set forth in the following claims.

What is claimed is:

1. A method of fabricating an integrated circuit electrode comprising:
forming a layer comprising noble metal oxide on an integrated circuit substrate; and
wrinkling the layer comprising noble metal oxide by removing at least some oxygen from the layer comprising noble metal oxide to thereby produce a wrinkled layer.

2. A method according to claim 1 wherein the forming comprises sputtering the layer comprising noble metal oxide on the integrated circuit substrate.

3. A method according to claim 1 wherein the forming comprises depositing the noble metal on the integrated circuit substrate in an oxygen-containing ambient.

4. A method according to claim 1 wherein the forming comprises depositing the noble metal on the integrated circuit substrate and oxidizing at least some of the noble metal.

5. A method according to claim 1 wherein the forming is preceded by forming a barrier layer on the integrated circuit substrate and wherein the forming comprises forming the layer comprising noble metal oxide on the barrier layer opposite the integrated circuit substrate.

6. A method according to claim 5 wherein the barrier layer comprises the noble metal.

7. A method according to claim 5 wherein the barrier layer comprises titanium nitride.

8. A method according to claim 1 wherein the noble metal comprises ruthenium.

9. A method according to claim 1 wherein the wrinkling comprises wrinkling the layer comprising noble metal oxide without uncovering an underlying region of the integrated circuit substrate directly beneath the wrinkled layer.

10. A method according to claim 1 wherein the wrinkling comprises exposing the layer comprising noble metal oxide to a reducing ambient to remove at least some oxygen from the layer comprising noble metal oxide.

11. A method according to claim 10 wherein the exposing comprises exposing the layer comprising noble metal oxide to a hydrogen containing ambient.

12. A method according to claim 11 wherein the hydrogen containing ambient consists of hydrogen.

13. A method according to claim 11 wherein the hydrogen containing ambient consists of between about 1% and about 100% hydrogen and between about 0% and about 99% inert gas.

14. A method according to claim 1 wherein the layer comprising noble metal oxide is at least 300 Å thick.

15. A method according to claim 1 wherein the wrinkling is followed by:
forming a dielectric layer on the wrinkled layer opposite the integrated circuit substrate; and
forming a conductive layer on the dielectric layer opposite the wrinkled layer to thereby form a capacitor.

16. A method according to claim 1 wherein the wrinkled layer is of smaller volume than the layer comprising noble metal oxide.

17. A method according to claim 1 wherein the wrinkled layer is thinner than the layer comprising noble metal oxide.

18. A method according to claim 1 wherein the wrinkling comprises removing all the oxygen from the layer comprising noble metal oxide to produce a wrinkled layer consisting essentially of noble metal.

19. A method according to claim 1 wherein the wrinkled layer includes a plurality of subhemispherical noble metal protrusions.

20. A method of fabricating an integrated circuit electrode comprising:
forming a layer comprising noble metal oxide on an integrated circuit substrate; and
wrinkling the layer comprising noble metal oxide by exposing the layer comprising noble metal oxide to a reducing ambient to thereby produce a wrinkled layer.

21. A method according to claim 20 wherein the forming is preceded by forming a barrier layer on the integrated circuit substrate and wherein the forming comprises forming the layer comprising noble metal oxide on the barrier layer opposite the integrated circuit substrate.

22. A method according to claim 20 wherein the wrinkling comprises wrinkling the layer comprising noble metal oxide without uncovering an underlying region of the integrated circuit substrate directly beneath the wrinkled layer.

23. A method according to claim 20 wherein the wrinkling comprises exposing the layer comprising noble metal oxide to the reducing ambient to remove at least some oxygen from the layer comprising noble metal oxide.

24. A method according to claim 23 wherein the exposing comprises exposing the layer comprising noble metal oxide to a hydrogen containing ambient.

25. A method according to claim 24 wherein the hydrogen containing ambient consists of hydrogen.

26. A method according to claim 24 wherein the hydrogen containing ambient consists of between about 1% and about 100% hydrogen and between about 0% and about 99% inert gas.

27. A method according to claim 20 wherein the layer comprising noble metal oxide is at least 300 Å thick.

28. A method according to claim 20 wherein the wrinkling is followed by:
forming a dielectric layer on the wrinkled layer opposite the integrated circuit substrate; and
forming a conductive layer on the dielectric layer opposite the wrinkled layer to thereby form a capacitor.

29. A method according to claim 20 wherein the wrinkled layer is of smaller volume than the layer comprising noble metal oxide.

30. A method according to claim 20 wherein the wrinkled layer is thinner than the layer comprising noble metal oxide.

31. A method according to claim 20 wherein the wrinkled layer includes a plurality of subhemispherical noble metal protrusions.

32. A method of fabricating an integrated circuit electrode comprising:
forming a layer comprising noble metal oxide on an integrated circuit substrate; and
wrinkling the layer comprising noble metal oxide by deoxidizing the layer comprising noble metal oxide to thereby produce a wrinkled layer.

33. A method according to claim 32 wherein the forming is preceded by forming a barrier layer on the integrated circuit substrate and wherein the forming comprises forming the layer comprising noble metal oxide on the barrier layer opposite the integrated circuit substrate.

34. A method according to claim 32 wherein the wrinkling comprises wrinkling the layer comprising noble metal oxide without uncovering an underlying region of the integrated circuit substrate directly beneath the wrinkled layer.

35. A method according to claim 32 wherein the wrinkling comprises exposing the layer comprising noble metal oxide to a reducing ambient to remove at least some oxygen from the layer comprising noble metal oxide.

36. A method according to claim 35 wherein the exposing comprises exposing the layer comprising noble metal oxide to a hydrogen containing ambient.

37. A method according to claim 36 wherein the hydrogen containing ambient consists of hydrogen.

38. A method according to claim 36 wherein the hydrogen containing ambient consists of between about 1% and about 100% hydrogen and between about 0% and about 99% inert gas.

39. A method according to claim 32 wherein the layer comprising noble metal oxide is at least 300 Å thick.

40. A method according to claim 32 wherein the wrinkling is followed by:
forming a dielectric layer on the wrinkled layer opposite the integrated circuit substrate; and
forming a conductive layer on the dielectric layer opposite the wrinkled layer to thereby form a capacitor.

41. A method according to claim 32 wherein the wrinkled layer is of smaller volume than the layer comprising noble metal oxide.

42. A method according to claim 32 wherein the wrinkled layer is thinner than the layer comprising noble metal oxide.

43. A method according to claim 32 wherein the wrinkled layer includes a plurality of subhemispherical noble metal protrusions.

44. A method of fabricating an integrated circuit electrode comprising:
forming a layer comprising metal and another constituent on an integrated circuit substrate; and
wrinkling the layer comprising metal and another constituent by removing at least some of the other constituent from the layer comprising metal and another constituent to thereby produce a winkled layer.

45. A method according to claim 44 wherein the metal comprises a noble metal and the other constituent comprises carbon, and wherein the wrinkling comprises heating the layer comprising noble metal and carbon to remove at least some of the carbon and wrinkle the layer comprising noble metal and carbon.

46. A method according to claim 44 wherein the metal comprises a noble metal and the other constituent comprises oxygen, and wherein the wrinkling comprises exposing the layer comprising noble metal and oxygen to a reducing ambient to remove at least some of the oxygen and wrinkle the layer comprising noble metal and oxygen.

47. A method according to claim 44 wherein the forming is preceded by forming a barrier layer on the integrated circuit substrate and wherein the forming comprises forming the layer comprising metal oxide on the barrier layer opposite the integrated circuit substrate.

48. A method according to claim 46 wherein the exposing comprises exposing the layer comprising noble metal oxide to the reducing ambient to wrinkle the layer comprising noble metal oxide without uncovering an underlying region of the integrated circuit substrate directly beneath the wrinkled layer.

49. A method according to claim 48 wherein the exposing comprises exposing the layer comprising noble metal oxide to a hydrogen containing ambient.

50. A method according to claim 44 wherein the wrinkling is followed by:
forming a dielectric layer on the wrinkled layer opposite the integrated circuit substrate; and
forming a conductive layer on the dielectric layer opposite the wrinkled layer to thereby form a capacitor.

51. A method according to claim 44 wherein the wrinkled layer is of smaller volume than the layer comprising metal and another constituent.

52. A method according to claim 44 wherein the wrinkled layer is thinner than the layer comprising metal and another constituent.

53. A method according to claim 44 wherein the wrinkled layer includes a plurality of subhemispherical metal protrusions.

54. A method of fabricating an integrated circuit electrode comprising:
forming a layer comprising metal and another constituent on an integrated circuit substrate; and
wrinkling the layer comprising metal and another constituent by reacting at least some of the metal with at least some of the other constituent to form a compound of the metal and the other constituent and thereby produce a wrinkled layer.

55. A method according to claim 54 wherein the metal comprises a noble metal and the other constituent comprises silicon, and wherein the wrinkling comprises heating the layer comprising noble metal and silicon to react at least some of the noble metal with at least some of the silicon to form a noble metal silicide.

56. A method according to claim 54 wherein the forming is preceded by forming a barrier layer on the integrated circuit substrate and wherein the forming comprises forming the layer comprising metal and another constituent on the barrier layer opposite the integrated circuit substrate.

57. A method according to claim 54 wherein the wrinkling is followed by:
forming a dielectric layer on the wrinkled layer opposite the integrated circuit substrate; and
forming a conductive layer on the dielectric layer opposite the wrinkled layer to thereby form a capacitor.

58. A method according to claim 54 wherein the wrinkled layer is of smaller volume than the layer comprising metal and another constituent.

59. A method according to claim 54 wherein the wrinkled layer is thinner than the layer comprising metal and another constituent.

60. A method according to claim 54 wherein the wrinkled layer includes a plurality of subhemispherical metal protrusions.

61. A method of fabricating an integrated circuit capacitor comprising:
forming a first layer comprising ruthenium on an integrated circuit substrate;
forming a second layer comprising ruthenium oxide on the first layer opposite the integrated circuit substrate;
exposing the second layer to a reducing ambient to produce a wrinkled second layer;
forming a third layer comprising tantalum oxide on the wrinkled second layer opposite the first layer; and
forming a fourth layer comprising ruthenium on the third layer opposite the second layer.

62. A method according to claim 61 wherein the exposing comprises annealing the second layer in an ambient comprising nitrogen.

63. A method according to claim 61 wherein the exposing comprises annealing the second layer in an ambient consisting of about 10% hydrogen and about 90% nitrogen at about 450 for about 30 minutes.

64. A method according to claim 61 wherein the flowing is performed between the forming a third layer and forming a fourth layer:
crystallizing the third layer comprising tantalum oxide.

65. A method according to claim 61 wherein the second layer is about 300 Å thick.

66. A method according to claim 61 wherein the wrinkled second layer comprises a plurality of subhemispheric protrusions.

67. A method according to claim 61 wherein the forming a second layer comprises sputtering ruthenium oxide on the first layer.

68. A method according to claim 61 wherein the forming a second layer comprises depositing ruthenium on the first layer in an oxygen containing ambient.

69. A method according to claim 61 wherein the forming a second layer comprises depositing ruthenium on the first layer and oxidizing at least some of the ruthenium.

70. A method according to claim 61 wherein the wrinkled second layer is of smaller volume than the second layer.

71. A method according to claim 61 wherein the wrinkled second layer is thinner than the second layer.

72. A method according to claim 61 wherein the wrinkled second layer includes a plurality of subhemispherical noble metal protrusions.

73. A method of fabricating an integrated circuit electrode comprising:
forming a layer comprising noble metal having a volume on an integrated circuit substrate; and
wrinkling the layer comprising noble metal by decreasing the volume of the layer comprising noble metal on the integrated circuit substrate.

74. A method according to claim 73 wherein the layer comprising noble metal is a layer comprising noble metal oxide and wherein the wrinkling comprises removing at least some oxygen from the layer comprising noble metal oxide.

75. A method according to claim 73 wherein the layer comprising noble metal is a layer comprising noble metal oxide and wherein the wrinkling comprises exposing the layer comprising noble metal oxide to a reducing ambient.

76. A method according to claim 73 wherein the layer comprising noble metal is a layer comprising noble metal oxide and wherein the wrinkling comprises deoxidizing the layer comprising noble metal oxide.

77. A method according to claim 73 wherein the layer comprising noble metal is a layer comprising noble metal and another constituent and wherein the wrinkling comprises removing at least some of the other constituent from the layer comprising noble metal and another constituent.

78. A method according to claim 73 wherein the layer comprising noble metal is a layer comprising noble metal and another constituent and wherein the wrinkling comprises reacting at least some of the metal with at least some of the other constituent.

79. A method according to claim 73 wherein the forming is preceded by forming a barrier layer on the integrated circuit substrate and wherein the forming comprises forming the layer comprising noble metal on the barrier layer opposite the integrated circuit substrate.

80. A method according to claim 73 wherein the wrinkling is followed by:
forming a dielectric layer on the layer comprising noble metal opposite the integrated circuit substrate; and
forming a conductive layer on the dielectric layer opposite the layer comprising noble metal to thereby form a capacitor.

81. A method according to claim 73 wherein the wrinkling comprises wrinkling the layer comprising noble metal by decreasing the volume of the layer comprising noble metal to form a plurality of subhemispherical noble metal protrusions.

82. An integrated circuit capacitor comprising:
a first layer comprising ruthenium on an integrated circuit substrate;
a second, wrinkled layer comprising a plurality of subhemispherical ruthenium protrusions on the first layer opposite the integrated circuit substrate;
a third layer comprising tantalum oxide on the second layer opposite the first layer; and
a fourth layer comprising ruthenium on the third layer opposite the second layer.

83. An integrated circuit capacitor according to claim 82 wherein the second, wrinkled layer consists essentially of the plurality of subhemispherical ruthenium protrusions on the first layer opposite the integrated circuit substrate.

84. An integrated circuit capacitor according to claim 82 wherein the second, wrinkled layer is free of superhemispherical ruthenium protrusions on the first layer opposite the integrated circuit substrate.

85. An integrated circuit capacitor comprising:
a wrinkled layer comprising a plurality of subhemispherical protrusions that comprise noble metal on an integrated circuit substrate;
a dielectric layer on the wrinkled layer opposite the integrated circuit substrate; and
a conductive layer on the dielectric layer opposite the wrinkled layer.

86. An integrated circuit capacitor according to claim 85 wherein the wrinkled layer consists essentially of the plurality of subhemispherical protrusions that comprise noble metal on the integrated circuit substrate.

87. An integrated circuit capacitor according to claim 85 wherein the wrinkled layer is free of superhemispherical protrusions that comprise noble metal on the integrated circuit substrate.

88. An integrated circuit capacitor according to claim 85 wherein the noble metal comprises ruthenium.

89. An integrated circuit electrode comprising:
a first layer comprising ruthenium on an integrated circuit substrate; and
a second, wrinkled layer comprising a plurality of subhemispherical ruthenium protrusions on the first layer opposite the integrated circuit substrate.

90. An integrated circuit electrode according to claim 89 wherein the second, wrinkled layer consists essentially of the plurality of subhemispherical ruthenium protrusions on the first layer opposite the integrated circuit substrate.

91. An integrated circuit electrode according to claim 89 wherein the second, wrinkled layer is free of superhemispherical ruthenium protrusions on the first layer opposite the integrated circuit substrate.

92. An integrated circuit electrode comprising:
an integrated circuit substrate; and
a wrinkled layer comprising a plurality of subhemispherical protrusions that comprise noble metal on the integrated circuit substrate.

93. An integrated circuit electrode according to claim 92 wherein the wrinkled layer consists essentially of the plurality of subhemispherical protrusions that comprise noble metal on the integrated circuit substrate.

94. An integrated circuit electrode according to claim 92 wherein the wrinkled layer is free of superhemispherical protrusions that comprise noble metal on the integrated circuit substrate.

95. An integrated circuit electrode according to claim 92 wherein the noble metal comprises ruthenium.
